(19) United States
(12) Patent Application Publication
(10) Pub. No.: US 2017/0074689 A1
(43) Pub. Date: Mar. 16, 2017

(54) Sensor Fusion Method for Determining Orientation of an Object

(71) Applicant: Dialog Semiconductor B.V., s-Hertogenbosch (NL)

(72) Inventors: Wessel Harm Lubberhuizen, Delden (NL); Robert MacAulay, Cambridge (GB)

(21) Appl. No.: 15/260,807

(22) Filed: Sep. 9, 2016

(30) Foreign Application Priority Data
Sep. 11, 2015 (DE) 102015217449.2

(51) Int. Cl. G01D 5/56

(52) U.S. Cl. CPC G01D 5/56; G01R 33/02

(57) ABSTRACT

A sensor fusion method of calculating an orientation of an object by combining readings from different types of orientation sensors to estimate the orientation of an object. An analytical solution is provided which is computationally efficient and can be implemented in fixed or floating point architecture. The method comprises receiving an input orientation; receiving a reading from a first orientation sensor; receiving a reading from a second orientation sensor; where said first and second orientation sensors are of different types; and determining an updated orientation by calculating a rotation based on the orientation sensor readings and applying the calculated rotation to the input orientation.

### TECHNICAL FIELD

The present disclosure relates to a sensor fusion method for determining the orientation of an object, together with corresponding apparatus.

### BACKGROUND

In order to estimate the orientation of an object it is known to combine data from multiple sensors associated with the object, including orientation sensors such as accelerometers, magnetometers and gyroscopes. These may be associated with an object so that they move and rotate together with the body of the object.

In the following, we assume a right-handed reference coordinate system is assumed in which x points in the north direction, y points east, and z points down.

A three-axis accelerometer provides acceleration measurements in m/s² along each of the x, y and z axes. Because gravity acts as a constant acceleration, an accelerometer can be used to measure orientation in the up-down plane.

A three-axis magnetometer measures the magnetic field (in microTesla) in the x, y and z axes. It can provide an absolute orientation in the x-y plane.

A three-axis gyroscope measures changes in orientation, providing angular velocities in rad/s along each of the x, y, z axes.

The orientation of the device can be determined from one, two or more of these types of orientation sensors, and possibly with additional types of orientation sensors as well. The operation of accelerometer, magnetometer and gyroscope devices are known, and many different types of each device are available, including devices based on microelectromechanical systems (MEMS) components. In addition, when these devices are used for measuring orientation of an object it is known to provide a plurality of one or more of accelerometers, magnetometers and gyroscopes to allow for better performance.

Orientation sensors are used for orientation determination in a wide variety of contexts, including automotive and other vehicles and for consumer electronics such as smart phones, tablet computers and wearable technology.

Whenever multiple sensors are provided, their outputs must be combined in order to yield a measurement of the object's orientation.

One well-known method of combining multiple sensor inputs is the Kalman filter, which uses a series of measurements observed over time and produces estimates of unknown variables that tend to be more precise than those based on a single measurement alone. It operates recursively on streams of noisy input data to produce a statistically optimal estimate of the underlying system state.

However, the problem of estimating the orientation of an object is non-linear, and the standard Kalman filter is linear. Therefore an extended Kalman filter must be applied. An example of this is described by Sabatini, “Quaternion-Based Extended Kalman Filter For Determining Orientation By Inertial And Magnetic Sensing”, IEEE Transactions On Biomedical Engineering, Vol. 53 No. 7, July 2006. This is a resource intensive and complex algorithm requiring matrix inversion floating point arithmetic. It therefore requires large processing resources to be applied, which can be a challenge particularly in the mobile environment.

Other approaches have been proposed which require lower processing resources, using iterative methods based on error feedback or steepest descent. Examples of these improved techniques can be seen in:
Mahoney Et Al, “Complementary Filter Design On The Special Orthogonal Group SO(3)”, Proceedings Of The 44^{th} IEEE Conference On Decision And Control, And European Control Conference Of 2005, Seville, Spain, Dec. 12-15, 2005
Madgwick, An Efficient Orientation Filter For Inertial And Inertial/Magnetic Sensor Arrays, 30 Apr. 2010.
Cavallo, Experimental Comparison Of Sensor Fusion Algorithms For Attitude Estimation, Preprints Of The 19^{th} World Congress Of The International Federation Of Automatic Control South Africa, Aug. 24-29, 2014.

A steepest descent algorithm starts from a point in the solution space, and finds a local minimum (or maximum) by moving to the next solution that represents the steepest gradient. It has steps of a fixed size, which lead to problems when the step size is either too small or too large. In practice this can result in very small improvement steps, requiring a lot of iterations and/or a very long time before the optimal solution is found.

These approaches therefore have problems converging to the optimal solution in cases when the distance between the current estimate and the optimal solution is large. Therefore while being relatively computationally efficient, they can struggle with certain real-world scenarios, for example when the optimization function is not convex, or has multiple local minima.

### SUMMARY

There is a need for a way of combining the outputs of various sensors which is computationally efficient and yet robust to cope with real-world situations.

According to a first aspect of the disclosure there is provided a method of calculating an orientation of an object comprising: receiving an input orientation; receiving a reading from a first orientation sensor; receiving a reading from a second orientation sensor; where said first and second orientation sensors are of different types; and determining an updated orientation by calculating a rotation based on the orientation sensor readings and applying the calculated rotation to the input orientation; wherein calculating a rotation comprises: calculating a first rotation which rotates the reading from one of the orientation sensors to be aligned with a first reference direction; applying the first rotation to the reading from the other of the orientation sensors to obtain an intermediate orientation; calculating a second rotation that rotates the intermediate orientation to be aligned with a reference plane which is spanned by axes including an axis aligned with the first reference direction; and combining the first and second rotations.

The readings from the first and second types of orientation sensors can be received in any order.

An orientation sensor is any sensor producing readings from which a three-axis representation of an object's orientation in space can be derived. This can be directly, through use of three-axis orientation sensors, or indirectly, through use of other readings from which three-axis representations can be calculated or inferred. An orientation sensor's “type” may be categorised by the nature of the data that it senses. Examples of different orientation sensor types include accelerometers, magnetometers and gyroscopes.

Optionally, calculating a second rotation comprises calculating a second rotation that rotates the intermediate orientation to be aligned with a second reference direction which is orthogonal to the first reference direction.

Optionally, the first sensor comprises an accelerometer and the second sensor comprises a magnetometer; and wherein calculating a first rotation comprises rotating the reading from the accelerometer into an accelerometer reference axis and rotating the reading from the magnetometer into a magnetometer reference plane.

Optionally, the accelerometer reference axis comprises a gravitational axis and the magnetometer reference plane comprises a north-down plane.

Optionally, the method further comprises receiving a reading from a third orientation sensor being of a different type from said first and second orientation sensors and wherein calculating a rotation comprises combining a third rotation derived from the third orientation sensor together with said first and second rotations.

Optionally, the third sensor comprises a gyroscope.

Optionally, calculating a rotation comprises applying a rotation to the input orientation based on the readings from the gyroscope to obtain a preliminary orientation; and then applying said first and second rotations to the preliminary orientation estimate.

Optionally, the first and second orientation sensor readings are converted to quaternion form and the calculated rotations comprise unit quaternions.

Optionally, the third orientation sensor reading is converted to quaternion form and the calculated rotations comprise unit quaternions.

Optionally, the combination of successive rotations comprises moving along the surface of a unit quaternion hypersphere.

Optionally, the sensors have different sampling rates; and wherein the method is repeated and makes use of any available readings that have been made at or between successive iterations of the method.

Optionally, the rotation applied for the readings of each sensor is modified according to a weight factor and the updated object orientation depends on the weighted contributions.

Optionally, the weight factors for each rotation depend on the relative noise levels associated with each sensor.

Optionally, the rotation is modified for each sensor before data from the next sensor is processed.

Optionally, the rotations for each sensor are modified after data from all the sensors have been processed.

Optionally, calculations that involve known zeros are omitted.

Optionally, the method is implemented in a floating point architecture.

Optionally, the method is implemented in a fixed point architecture.

According to a second aspect of the disclosure there is provided apparatus for determining the orientation of an object comprising one or more sensors associated with the object, and a processor arranged to: receive an input orientation; receive a reading from a first orientation sensor; receive a reading from a second orientation sensor, where said first and second orientation sensors are of different types; and to determine an updated orientation by calculating a rotation based on the orientation sensor readings and apply the calculated rotation to the input orientation; wherein calculating a rotation comprises calculating a first rotation which rotates the reading from one of the orientation sensors to be aligned with a first reference direction; applying the first rotation to the reading from the other of the orientation sensors to obtain an intermediate orientation; calculating a second rotation that rotates the intermediate orientation to be aligned with a reference plane which is spanned by axes including an axis aligned with the first reference direction; and combining the first and second rotations.

### BRIEF DESCRIPTION OF THE DRAWINGS

The present disclosure will now be described by way of example only with reference to the accompanying drawings in which:

FIG. 1 shows an embodiment of a sensor fusion method for determining the orientation of an object, according to one example of the disclosure;

FIGS. 2 and 3 illustrate aspects of a unit quaternion representation of rotations;

FIGS. 4 and 5 illustrate aspects of a method of determining the orientation of an object according to an embodiment of the disclosure; and

FIG. 6 illustrates the performance of a sensor fusion method according to the disclosure as compared with other techniques.

### DESCRIPTION

According to the present disclosure an object's orientation may be calculated by determining a rotation composed of a sequence of sub-rotations contributed by a plurality of orientation sensors. The rotational contributions from the plurality of orientation sensors comprise a sequence of successive orthogonal rotations. A first sub-rotation moves a reading from a first orientation sensor into a first reference direction, and is followed by a second sub-rotation which moves a reading from a second orientation sensor into a reference plane, or a second reference direction. When moved to a reference plane, one of the spanning axes of the plane is defined by the direction of the first reference axis. When moved to a second reference axis, the second reference axis is orthogonal to the first reference axis. The orthogonality of the first reference direction with the second reference plane or direction means that the second applied sub-rotation does not change the rotated first reading, so an analytic solution can be provided.

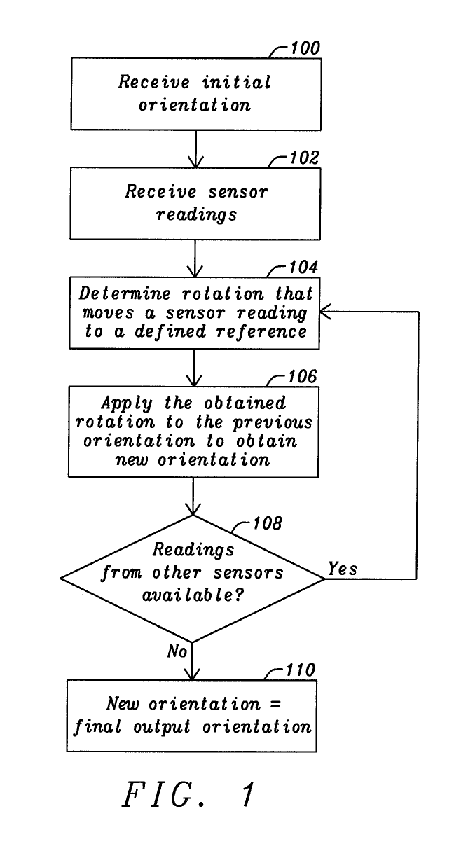

As shown in FIG. 1, at step 100 an initial orientation is received. This may be a previous orientation or when the system starts up it may be a reference orientation used as a starting point for the measurements. At step 102 sensor readings are received. The present disclosure relates to systems where two or more types of sensors are present. However at step 102 it is possible that readings are only received from a single type of sensor, as different sensors may be sampled at different rates. In general, time-correlated readings from one, two or more types of sensor may be received at step 102.

A rotation is calculated that moves a first reading from a first sensor to a defined reference frame or axis, at step 104. Then, at step 106, the rotation represented by the transformed first sensor measurement is applied to the initial orientation previously received at step 100. The result of this is a new, intermediate, orientation, representing the effect of the first sensor on the received initial orientation. Step 108 checks if other sensor readings are available. If time-correlated data is available from other sensors, then steps 104 and 106 are repeated. A second successive rotation is determined which moves the reading from the second sensor to a defined reference frame or axis. That rotation is then applied to the intermediate orientation that was derived from the first sensor reading. The process is repeated for any third and subsequent sensor readings, until all the sensor readings have been processed. After that time, the end result is output as the final orientation, at step 110. This final orientation then acts as the initial orientation received at step 100 for the next iteration of the process.

Each calculation is an analytic solution performed in a space that makes an assumption about the axis of sensitivity. It takes advantage of the fundamental nature of the particular type of data that is gathered by each sensor, to truncate data in a direction of rotation which each particular sensor is insensitive to. The directions which are discounted will be orthogonal between different sensor types.

In one embodiment the rotations are represented by unit quaternions. The use of quaternions is computationally simpler as compared with Euler angles or rotation matrices, and avoids singularities (gimbal lock).

A quaternion is a complex number of the form w+xi+yj+zk, where w, x, y, z are real numbers and i, j, k are imaginary units wherein i²=j²=k²=ijk=−1. A quaternion represents a point in four dimensional space. Constraining a quaternion to have unit magnitude (where w²+x²+y²+z²=1) yields a three-dimensional space equivalent to the surface of a hypersphere, so the unit quaternion is an efficient way of representing Euclidian rotations in three dimensions. The vector part of the unit quaternion (x, y, z components) represents a radius of a 2-sphere corresponding to an axis of rotation, and its magnitude gives the angle of rotation.

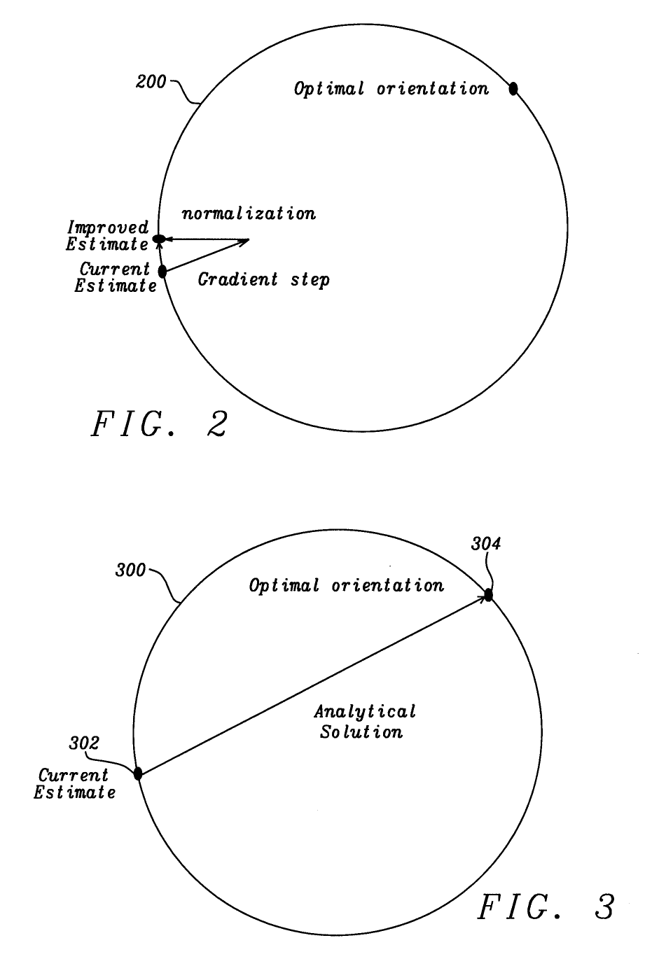

FIGS. 2 and 3 illustrate quaternion hyperspheres 200, 300. A unit quaternion sphere has four dimensions and a diameter of unity. Each quaternion is a point on the sphere.

FIG. 2 illustrates the prior art techniques, which as discussed above require a normalisation between each gradient step when moving from a current estimate to another estimate and involve moving through the inside of the sphere rather than along its surface. To get to the optimal orientation many successive iterations are required, with normalization required after every iterative step to return to the surface, which is a computational burden that the present disclosure avoids.

According to the disclosure, a combined rotation is derived as a combination of a first rotation and a second rotation, which are preferably orthogonal to each other. Each of the first and second rotations are calculated analytically in the reference frame. Intuitively, this can be understood by realizing that the quaternion that represents an orientation is a point on a hyper sphere. An example of this is illustrated in FIG. 3, where a transition from one point 302 to another 304 on the sphere 300 is provided by a spherical linear interpolation. This analytical solution converges directly to the optimal solution. Note that there are two quaternions that represent each rotation, so the shortest path is chosen.

We will now illustrate one example embodiment of the disclosure, in which the rotation reference frame is formed of unit quaternions and the sensors whose data is combined comprise a gyroscope, an accelerometer and a magnetometer.

A right-handed reference coordinate system is assumed in which x points in the north direction, y points east, and z points down. The z-axis is a gravitational axis. If the sensors are not already oriented in this fashion, an appropriate transformation matrix can be applied.

Inputs for the process are:

| | |
|---|---|
| gs | Vector of gyroscope samples [gs.x, gs.y, gs.z] |
| as | Normalised vector of acceleration samples [as.x, as.y, as.z] |
| ms | Normalised vector of magnetometer samples [ms.x, ms.y, ms.z] |
| qp | Previous orientation in unit quaternion form, qp = [qp.w, qp.x, qp.y, |
| | qp.z] |

This assumes that the raw x, y and z data output by the accelerometer and magnetometer are normalised such that (x²+y²+z²=1). It is possible that the sensors output normalised data directly, but if the data is not already normalised a normalisation step can be carried out prior to continuing with the process, or as a preliminary stage at each step when the data from each sensor is first processed.

The result of the process is:

| | |
|---|---|
| qn | Next orientation in unit quaternion form qn = [qn.w, qn.x, qn.y, qn.z] |

in one example, the following steps are performed to find qn, based on gs, as, ms, and qp.

Step 1

Compute a scaled gyroscope vector Ω:

Ω=[gs.x, gs.y, gs.z]×gyro_sensitivity/gyro_sample_rate

Where the gyro_sensitivity factor converts the gyro measurements to rad/sec, and the gyro_sample rate is the sampling rate in Hz. The gyro sensor data may have been previously high-pass filtered to remove any offset and/or low frequency noise. The gyro sensor data may been previously low-pass filtered to reduce high frequency noise.

Step 2

To transform the scaled sensor reading Ω into a rotational representation, a unit quaternion qg is formed using:

$$qg = [ 1 - sqrt ( Ω \cdot {x}^{2} + Ω \cdot {y}^{2} + Ω \cdot {z}^{2} ) , Ω \cdot x , Ω \cdot y , Ω \cdot z ] when$$

$$\vert Ω \vert < 1$$

$$qg = [ 1 , 0 , 0 , 0 ] otherwise$$

Cases where |Ω|<1 represent valid outputs of the gyro. In other cases, a null quaternion is formed, as here the readings indicate that the output should be ignored.

Step 3

The effect of the gyroscope is applied to the previous orientation using:

qi=qp [symbol] qg

Where [symbol] denotes the quaternion product. The quaternion qi denotes a first intermediate orientation, formed by rotating the previous orientation according to the gyroscope readings.

Step 4

From the accelerometer readings (as), we compute the earth frame accelerometer vector ae, by rotating the measured accelerometer values with a rotation represented by the first intermediate orientation qi:

ae=qi [symbol] as [symbol] conjugate (qi)

Before carrying out this calculation, the accelerometer reading (as) is augmented to a quaternion with component as.w=0. An alternative way to compute the same result is to transform the quaternion qi to a rotation matrix, and apply the matrix to as.

Step 5

A rotation is computed that rotates the vector ae to an accelerometer reference direction. The axis of rotation is chosen to be perpendicular to the accelerometer reference direction. Such a rotation can be represented by a quaternion qa′, which may be computed as;

qa′=[Sa(1+ae.z), ae.y, −ae.x, 0] if ae.z≠−1

qa′=[0, 1, 0, 0] otherwise

The scaling factor Sa, (0<Sa≦1) can be used to reduce the effect of measurement noise. A lower value for Sa will reduce the effect of noise.

Subsequently, a unit quaternion qa can be formed by dividing the quaternion qa′ by its length:

qa=qa′/|qa′|

According to a preferred embodiment, the accelerometer reference direction may be the z-axis (also referred to as the gravitational axis or a down direction) although it is to be appreciated that other references may be chosen.

Step 6

The rotation qa found in step 5 is applied to the applied to the first intermediate orientation estimate (qi), to find a second intermediate orientation estimate qr.

When qa is a unit quaternion this may be computed as:

qr=qa [symbol] qi

Where [symbol] denotes the quaternion product.

Step 7

The second intermediate orientation estimate (qr) is used to transform the magnetic vector ms to the estimated earth frame magnetic vector mr. This can be computed as:

mr=qr [symbol] ms [symbol] conjugate (qr)

Where [symbol] is the quaternion product, and ms is augmented to a quaternion with component ms.w=0.

As an alternative, a rotation matrix may be formed from qr, and applied to ms. This may result in a lower number of computations as compared with the quaternion product method mentioned above.

Step 8

Subsequently, an inclination compensated magnetic vector ma is formed that discards the z component of the estimated earth frame magnetic vector. This may be computed as:

$$ma = [ mr . x , mr . y , 0 ] / sqrt ( mr . {x}^{2} + mr . {y}^{2} ) if mr . x \neq 0$$

$$or mr . y \neq 0 , \\ ma = [ 1 , 0 , 0 ] otherwise$$

If mr.x and mr.y are both zero, this is special situation, and ma is set to a the magnetic north direction.

Step 9

Then a rotation around the z axis is computed that rotates the inclination compensated magnetic vector ma to the magnetic reference direction (1,0,0). A quaternion qm′ that represents this rotation may be computed as:

$${qm}^{′} = [ Sm ( 1 + ma . x ) , 0 , 0 , - ma . y ] when ma . x \geq ma\_xmin$$

$${qm}^{′} = [ Sm ( ma . y ) , 0 , 0 , ma . x - 1 ] when - 1 < ma . x < ma\_xmin$$

$${qm}^{′} = [ 0 , 0 , 0 , 1 ] otherwise$$

Where ma_xmin is a threshold value (−1<ma_xmin<1) that is used to select the computation for qm that is results in the lowest numerical error. A possible value for ma_xmin is zero.

Sm is a scaling factor (0<Sm≦1), which can be used to reduce the effects of measurement noise in the magnetic sensor data.

Subsequently, a unit quaternion qm is computed by dividing qm′ by its length:

qm=qm′/|qm′|

Step 10

The rotation qm is then applied to the intermediate orientation estimate qr, to form an improved orientation estimate qs. In unit quaternion form this may be computed as:

qs=qm [symbol] qr

Step 11

A combined orientation estimate is computed using a weighted sum of the intermediate orientation estimates:

qt=α×qi+β×qr+γ×qs

Where alpha, beta and gamma are weight factors with a range 0-1, subject to the condition:

α+β+γ=1

α, β, γ can be tuned for optimal performance. The optimal values depend on the relative noise levels of the gyroscope data, accelerometer data and magnetometer data.

Step 12

The quaternion qn is computed by normalizing the quaternion qt. When the length of qt is zero, then qn is set to qp.

$$qn = q t / \vert q t \vert if \vert q t \vert \neq 0$$

$$qn = qp otherwise$$

It is to be appreciated that the above embodiment (steps 1-12) is just one example of how a method according to the disclosure may operate. The disclosure does not require that all of steps 1-12 be present, and also envisages variations to how each of steps 1-12 may be carried out.

In particular, it is not necessary for all three of the sensor types to be present. The disclosure can still function if one or more of these sensor types are missing, or indeed can also function with other types of sensor not limited to accelerometers, magnetometers and gyroscopes.

For example, if data from a gyroscope is unavailable, steps 1 to 3 can be omitted. In this case, at Step 4 the earth frame acceleration vector ae can be calculated based on the interpolation of the accelerometer reading (as) with qp directly. The remainder of the steps then carry on as before, with qi=qp in the weighted sum of step 11.

Also, if data from an accelerometer is unavailable, steps 4 to 6 can be omitted. In this case the first intermediate quaternion qi (derived from the effect of the gyroscope) is applied to the magnetic vector ms at step 7. The remainder of the steps then carry on as before, with qr=qi in the weighted sum of step 11.

Furthermore, if data from the magnetometer is unavailable, steps 7-10 can be omitted. The remainder of the steps then carry on as before, with qs=qr in the weighted sum of step 11.

Data from one of the sensors may not be available if the device whose orientation is being sensed is not equipped with the complete set of sensors. Also, the sensors may have different sampling rates so at any given time readings from a slower-sampled sensor may be absent. In that case, a new orientation can still be calculated based on the readings which are present. The method will also work if only one sensor reading is present.

The processing steps can be executed in floating point or fixed point precision, and implemented as dedicated hardware blocks (with optional resource sharing) or on a central processing unit with the steps prescribed executed as a software/firmware program.

In the implementation multiplications with known zeros can be omitted to reduce processing load.

Optionally, the square and reciprocal square root functions may be approximated by polynomials to reduce processing load.

Input data gs, as, ms, may be filtered, or calibrated, compensating for offsets, gain differences, and cross talk.

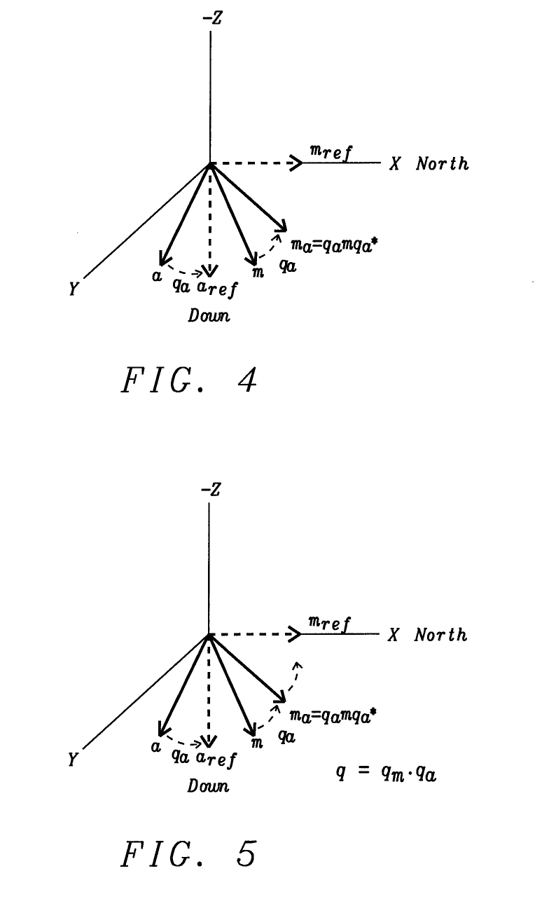

FIGS. 4 and 5 illustrate the application of successive orthogonal rotations to accelerometer and magnetometer readings. A rotation, q, is found which rotates an accelerometer reading, a, to a reference aref and also rotates a magnetometer reading, m, to a reference mref. The accelerometer reference aref is the gravitational axis (downwards direction) and the magnetometer reference mref is a direction in the y=0 (north-down) plane. FIG. 4 shows the application of a first sub-rotation qa to the accelerometer reading that rotates the accelerometer vector, a, into the earth z direction. This rotation qa has a rotation axis in z=0, and is also applied to the magnetometer reading to obtain a rotated magnetometer reading ma.

As shown in FIG. 5, a second sub-rotation qm is then applied to the rotated magnetometer reading ma. This rotation qm has a rotation axis along z and rotates the rotated magnetometer reading ma into the north-down plane (where y=0). Note that qm does not rotate aref because it is about the z=0 axis. The rotation q is then comprised of the rotation qa followed by qm; q=qm.qa.

The present disclosure improves the response time and the accuracy of the orientation sensor fusion, with lowest possible computational complexity.

It provides accurate instantaneous result after power-up, wake-up or sudden change with a much lower computational complexity than the Extended Kalman Filter, and works even when sensor data is only partially available.

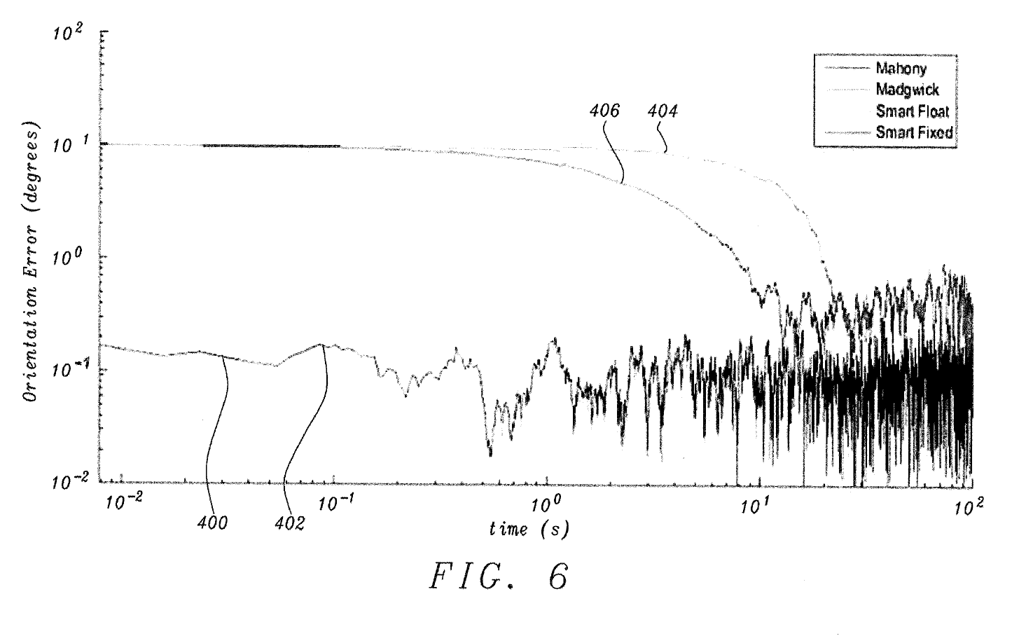

The graph of FIG. 6 illustrates the benefits from the new algorithm (labelled “Smart”) for simulated noisy sensor data. The absolute error between the true orientation and the estimated orientation is shown as a function of time. Here, the sample rate is 128 Hz and the initial error in the orientation is 10 degrees.

The Smart system algorithm acquires a very good estimate of the orientation, with an error less than 0.2 degrees within 1 sample. In contrast, the iterative Mahony 406 and Madgwick 404 algorithms require 10-20 seconds to converge, and are only accurate up to 0.5-1.0 degrees. The fixed point 400 and floating point 402 versions of the Smart algorithm work equally well.

Various improvements and modifications can be made to the above without departing from the scope of the present disclosure.

What is claimed is:

1. A method of calculating an orientation of an object comprising:
receiving an input orientation;
receiving a reading from a first orientation sensor;
receiving a reading from a second orientation sensor; where said first and second orientation sensors are of different types; and
determining an updated orientation by calculating a rotation based on the orientation sensor readings and applying the calculated rotation to the input orientation;
wherein calculating a rotation comprises:
calculating a first rotation which rotates the reading from one of the orientation sensors to be aligned with a first reference direction;
applying the first rotation to the reading from the other of the orientation sensors to obtain an intermediate orientation;
calculating a second rotation that rotates the intermediate orientation to be aligned with a reference plane which is spanned by axes including an axis aligned with the first reference direction; and
combining the first and second rotations.

2. The method of claim 1, wherein calculating a second rotation comprises calculating a second rotation that rotates the intermediate orientation to be aligned with a second reference direction which is orthogonal to the first reference direction.

3. The method of claim 1, wherein the first sensor comprises an accelerometer and the second sensor comprises a magnetometer; and wherein
calculating a first rotation comprises rotating the reading from the accelerometer into an accelerometer reference axis and rotating the reading from the magnetometer into a magnetometer reference plane.

4. The method of claim 3, wherein the accelerometer reference axis comprises a gravitational axis and the magnetometer reference plane comprises a north-down plane.

5. The method of claim 1, further comprising receiving a reading from a third orientation sensor being of a different type from said first and second orientation sensors and wherein calculating a rotation comprises combining a third rotation derived from the third orientation sensor together with said first and second rotations.

6. The method of claim 5, wherein the third sensor comprises a gyroscope.

7. The method of claim 6, wherein calculating a rotation comprises applying a rotation to the input orientation based on the readings from the gyroscope to obtain a preliminary orientation; and then applying said first and second rotations to the preliminary orientation estimate.

8. The method of claim 1, wherein the first and second orientation sensor readings are converted to quaternion form and the calculated rotations comprise unit quaternions.

9. The method of claim 5, wherein the third orientation sensor reading is converted to quaternion form and the calculated rotations comprise unit quaternions.

10. The method of claim 9, wherein the combination of successive rotations comprises moving along the surface of a unit quaternion hypersphere.

11. The method of claim 1, wherein the sensors have different sampling rates; and wherein the method is repeated and makes use of any available readings that have been made at or between successive iterations of the method.

12. The method of claim 1, wherein the rotation applied for the readings of each sensor is modified according to a weight factor and the updated object orientation depends on the weighted contributions.

13. The method of claim 12, wherein the weight factors for each rotation depend on the relative noise levels associated with each sensor.

14. The method of claim 12 wherein the rotation is modified for each sensor before data from the next sensor is processed.

15. The method of claim 12 wherein the rotations for each sensor are modified after data from all the sensors have been processed.

16. The method of claim 1, wherein calculations that involve known zeros are omitted.

17. The method of claim 1, implemented in a floating point architecture.

18. The method of claim 1, implemented in a fixed point architecture.

19. An apparatus for determining the orientation of an object comprising one or more sensors associated with the object, and a processor arranged to receive an input orientation; receive a reading from a first orientation sensor; receive a reading from a second orientation sensor, where said first and second orientation sensors are of different types; and to determine an updated orientation by calculating a rotation based on the orientation sensor readings and apply the calculated rotation to the input orientation; wherein calculating a rotation comprises calculating a first rotation which rotates the reading from one of the orientation sensors to be aligned with a first reference direction; applying the first rotation to the reading from the other of the orientation sensors to obtain an intermediate orientation; calculating a second rotation that rotates the intermediate orientation to be aligned with a reference plane which is spanned by axes including an axis aligned with the first reference direction; and combining the first and second rotations.

20. The apparatus of claim 19, wherein calculating a second rotation comprises calculating a second rotation that rotates the intermediate orientation to be aligned with a second reference direction which is orthogonal to the first reference direction.

21. The apparatus of claim 19, wherein the first sensor comprises an accelerometer and the second sensor comprises a magnetometer; and wherein
calculating a first rotation comprises rotating the reading from the accelerometer into an accelerometer reference axis and rotating the reading from the magnetometer into a magnetometer reference plane.

22. The apparatus of claim 21, wherein the accelerometer reference axis comprises a gravitational axis and the magnetometer reference plane comprises a north-down plane.

23. The apparatus of claim 19, which receives a reading from a third orientation sensor being of a different type from said first and second orientation sensors and wherein calculating a rotation comprises combining a third rotation derived from the third orientation sensor together with said first and second rotations.

24. The apparatus of claim 23, wherein the third sensor comprises a gyroscope.

25. The apparatus of claim 24, wherein calculating a rotation comprises applying a rotation to the input orientation based on the readings from the gyroscope to obtain a preliminary orientation; and then applying said first and second rotations to the preliminary orientation estimate.

26. The apparatus of claim 19, wherein the first and second orientation sensor readings are converted to quaternion form and the calculated rotations comprise unit quaternions.

27. The apparatus of claim 23, wherein the third orientation sensor reading is converted to quaternion form and the calculated rotations comprise unit quaternions.

28. The apparatus of claim 27, wherein the combination of successive rotations comprises moving along the surface of a unit quaternion hypersphere.

29. The apparatus of claim 19, wherein the sensors have different sampling rates; and wherein the method is repeated and makes use of any available readings that have been made at or between successive iterations of the method.

30. The apparatus of claim 19, wherein the rotation applied for the readings of each sensor is modified according to a weight factor and the updated object orientation depends on the weighted contributions.

31. The apparatus of claim 30, wherein the weight factors for each rotation depend on the relative noise levels associated with each sensor.

32. The apparatus of claim 30, wherein the rotation is modified for each sensor before data from the next sensor is processed.

33. The apparatus of claim 30, wherein the rotations for each sensor are modified after data from all the sensors have been processed.

34. The apparatus of claim 19, wherein calculations that involve known zeros are omitted.

35. The apparatus of claim 19, implemented in a floating point architecture.

36. The apparatus of claim 19, implemented in a fixed point architecture.
